(19) United States
(12) Patent Application Publication
(10) Pub. No.: US 2009/0121214 A1
(43) Pub. Date: May 14, 2009

(54) III-NITRIDE SEMICONDUCTOR LIGHT-EMITTING DEVICE AND MANUFACTURING METHOD THEREOF

(75) Inventors: Po Min Tu, Chiayi County (TW); Shih Cheng Huang, Hsinchu City (TW); Ying Chao Yeh, Taipei County (TW); Wen Yu Lin, Taichung City (TW); Peng Yi Wu, Taichung City (TW); Chih Peng Hsu, Tainan County (TW); Shih Hsiung Chan, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., Hsinchu County (TW)

(21) Appl. No.: 12/268,650

(22) Filed: Nov. 11, 2008

(30) Foreign Application Priority Data
Nov. 14, 2007 (TW) 096142955

(51) Int. Cl. H01L 33/00

(52) U.S. Cl. 257/13; 438/47; 257/E33.034

(57) ABSTRACT

A semiconductor light-emitting device comprises a substrate, a buffer layer, an n-type semiconductor layer, a conformational active layer and a p-type semiconductor layer. The n-type semiconductor layer includes a first surface and a second surface, and the first surface directly contacts the buffer layer. The second surface has a plurality of recesses, and a conformational active layer formed on the second surface and within the plurality of recesses. Therefore, the stress between the n-type semiconductor layer and the conformational active layer can be released with the recesses.

### BACKGROUND OF THE INVENTION

(A) Field of the Invention

The present invention relates to a III-nitride semiconductor light-emitting device and the manufacturing method thereof, and more particularly to a III-nitride semiconductor light-emitting device for releasing the stress between an conformational active layer and an n-type semiconductor layer.

(B) Description of the Related Art

Light-emitting diodes (LED) have been widely used in various products and have recently become an important research topic in photo-electronic semiconductor materials for producing blue light LED. Materials currently used for blue light LED include ZnSe, SiC, and InGaN, which are semiconductor materials exhibiting band gap properties with the gap energy of approximately over 2.6 eV. As the GaN series of light-emitting materials exhibits direct gap properties, they are able to generate light with high luminance and have the advantage of longer lifetime compared to the other similar direct gap material, such as ZnSe.

Typically, the structure of a blue light LED includes active layers of an InGaN/GaN quantum well structure. The quantum well structure is formed between an n-type GaN layer and a p-type GaN layer. When InGaN is grown with a high Indium content on GaN, there occurs a lattice mismatch between the GaN and the InGaN layer, and thus physical stress is induced between each of the layers. Therefore, an electric potential is generated to form piezoelectricity in response to the stress, resulting in a degradation of emission efficiency of the active layer.

FIG. 1 is a cross section diagram showing a light-emitting diode disclosed in U.S. Pat. No. 6,345,063. The light-emitting diode 10 comprises a substrate 11, a buffer layer 12, a n-type InGaN layer 13, an active layer 14, a first p-type III-V nitride layer 15, a second p-type III-V nitride layer 16, a p-type electrode 17 and an n-type electrode 18. The lattice constant of the active layer 14 matches that of the n-type InGaN layer 13, and thus the stress between these two layers is released. However, the n-type InGaN layer 13 is typically formed at a low temperature, which affects the quality of the epitaxial layers compared to the prior art GaN layer.

FIG. 2 is a cross section diagram showing a light-emitting diode disclosed in U.S. Pat. No. 6,861,270. The light-emitting diode 20 comprises a substrate 21, an n-type AlGaN layer 22, an active layer 23, a p-type AlGaN layer 24 and Ga or Al droplets 25. Due to the droplets 25 formed on the n-type AlGaN layer 22, a spatial fluctuation is produced in the bandgap such that light emission is better at the locations where the band gap is narrow. As a result, the light emitting efficiency can be increased even when dislocations are present. This patent discloses that the spatial fluctuation is produced by the lattice mismatch, and therefore this method is irrelevant to the solution of the lattice mismatch.

FIG. 3 is a cross section diagram showing a light-emitting diode disclosed in U.S. Pat. No. 7,190,001. The light-emitting diode 30 comprises a sapphire substrate 31, an AlN buffer layer 32, an n-type cladding layer 33, an AlN uneven layer 34, an active layer 35, a p-type cladding layer 36, a contact layer 37, a transparent electrode 38, a p-type electrode 391 and an n-type electrode 392. On the AlN uneven layer 34, the active layer 35 is formed. Therefore, the formation requirements of the active layer 35 can be simplified. However, the AlN uneven layer 34 is formed on the n-type cladding layer 33 by specific thermal treatment, which affects the quality of the epitaxial layers formed on the substrate.

In summary, the current market needs a semiconductor light-emitting device that can ensure low cost, high emission efficiency, and ease of implementation to eliminate all the drawbacks of the prior art described above.

### SUMMARY OF THE INVENTION

One aspect of the present invention is to provide a III-nitride semiconductor light-emitting device and a manufacturing method thereof for reducing the stress between the epitaxial layers. As a result, the emission efficiency of a light-emitting device can be increased due to the quantum confined stark effect (QCSE) on the recombination rate of electrons and holes.

A semiconductor light-emitting device according to one aspect of the present invention comprises: a substrate; a first type semiconductor layer including a first surface and a second surface, wherein the first surface is disposed adjacent to the substrate, and the second surface has a plurality of recesses and is opposite to the first surface; a conformational active layer formed on the second surface and within the plurality of recesses, wherein the stress between the first type semiconductor layer and the conformational active layer can be released with the recesses; and a second type semiconductor layer formed on the conformational active layer.

The III-nitride semiconductor light-emitting device further comprises a buffer layer disposed between the substrate and the first type semiconductor layer.

The depths of accesses are larger than the depth of a single quantum well in the conformational active layer, and are smaller than the depth of the first type semiconductor layer. The widths of the upper portions of the recesses range from 0.1 um to 10 um. The plurality of recesses have different sizes. The distribution of the plurality of recesses is substantially uniform or non-uniform. The widths of the upper portions of the recesses are larger than those of the lower portions of the recesses.

The active layer is formed to have a single quantum well structure or a multiple quantum well structure. The first type semiconductor layer is an n-type semiconductor layer, and the second type semiconductor layer is a p-type semiconductor layer.

The present invention discloses a method for manufacturing a III-nitride semiconductor light-emitting device. The method comprises the steps of: providing a substrate; forming a first type semiconductor layer on the substrate, wherein the first type semiconductor layer includes a first surface and a second surface, and wherein the first surface is disposed adjacent to the substrate, and the second surface has a plurality of recesses and is opposite to the first surface; forming a conformational active layer on the first type semiconductor layer; and forming a second type semiconductor layer on the conformational active layer.

The plurality of recesses are formed by etching the second surface of the first type semiconductor layer. The plurality of recesses are cavities formed on the second surface by controlling a flow rate of nitrogen, ammonia, hydrogen, TMGa, TEGa, TMIn, TEIn, or organometallic compound. The plurality of recesses are formed by the metal-organic chemical vapor deposition (MOCVD) method. The method further comprises at least one buffer layer directly formed on the substrate.

### BRIEF DESCRIPTION OF THE DRAWINGS

The objectives and advantages of the present invention will become apparent upon reading the following description and upon reference to the accompanying drawings in which:

FIG. 1 is a cross section diagram showing a light-emitting diode disclosed in U.S. Pat. No. 6,345,063;

FIG. 2 is a cross section diagram showing a light-emitting diode disclosed in U.S. Pat. No. 6,861,270;

FIG. 3 is a cross section diagram showing a light-emitting diode disclosed in U.S. Pat. No. 7,190,001;

FIG. 4 is a cross section diagram showing a light-emitting diode of the present invention;

FIG. 5A is a partial cross section diagram showing a light-emitting diode of the present invention; and

FIG. 5B is a top view of the partial cross section diagram of FIG. 5A.

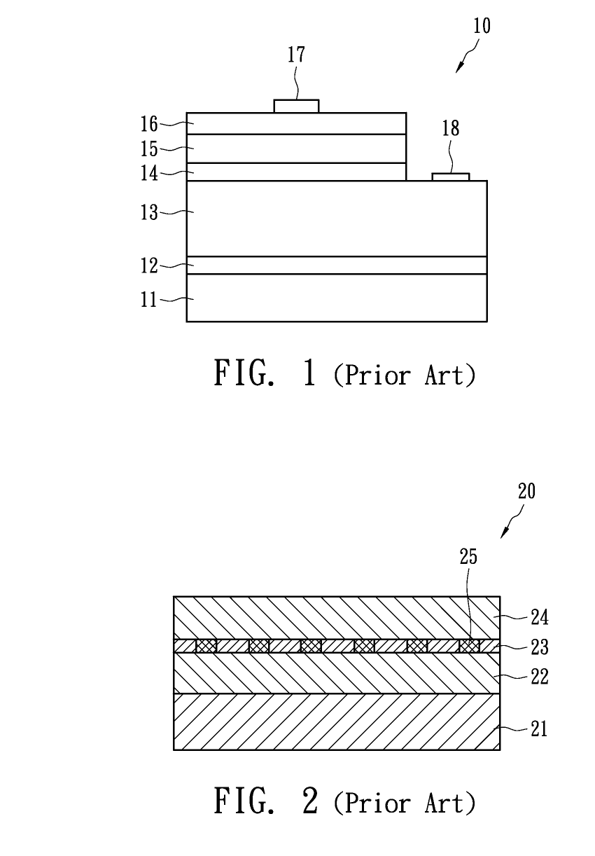

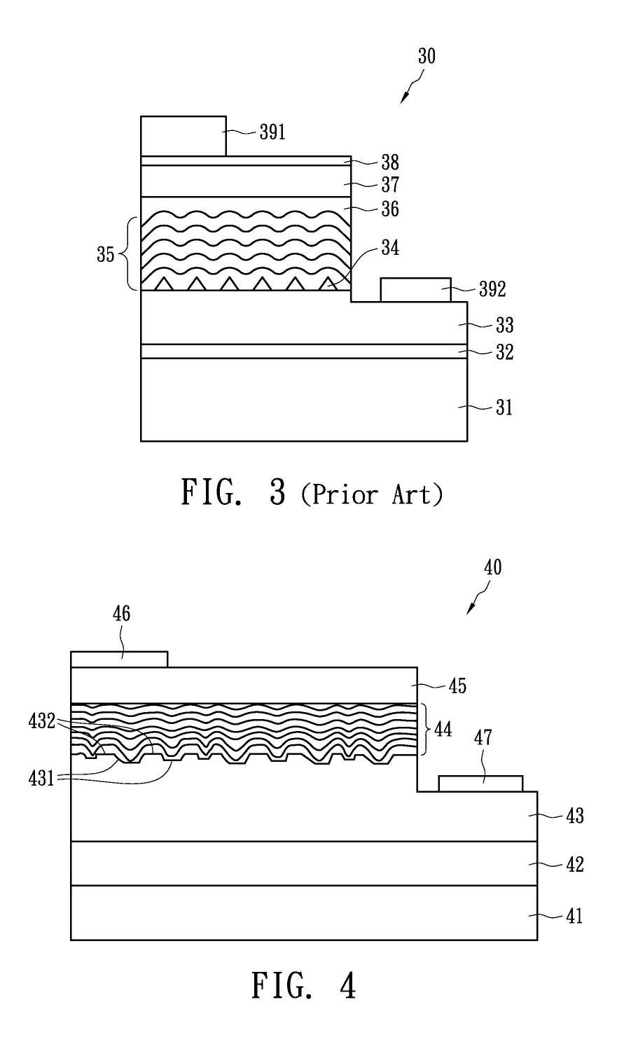

### DETAILED DESCRIPTION OF THE INVENTION

FIG. 4 is a cross section diagram showing a light-emitting diode of the present invention. The light-emitting diode 40 comprises a substrate 41, a buffer layer 42, an n-type (or first type) semiconductor layer 43, a conformational active layer 44 and a p-type (or second type) semiconductor layer 45. A p-type electrode 46 is formed on the p-type semiconductor layer 45 and an n-type electrode 47 is formed on the n-type semiconductor layer 43.

The substrate 41 can be formed by any known or later developed substrate materials, such as, for example, sapphire (i.e. Al₂O₃), silicon carbide (SiC), silicon, zinc oxide (ZnO), magnesium oxide (MgO) or gallium arsenide (GaAs). Subsequently, a semiconductor material is deposited over the substrate 41. Since the lattice mismatch occurs between the substrate 41 and the semiconductor material, at least one buffer layer 42 is required to form on the substrate 41. The buffer layer 42 is typically made of either GaN, InGaN, AlGaN or a superlattice structure whose hardness is lower than that of the traditional buffer layer with aluminum. The n-type semiconductor layer 43 is then formed on the buffer layer 42. The n-type semiconductor layer 43 may be formed as an n-type Si-doped GaN layer, epitaxially grown on the buffer layer 42. The top surface of the n-type semiconductor layer 43 is uneven and comprises a plurality of recesses 431 and a flat area 432. Recesses 431 are grown in a MOCVD furnace. After the n-type semiconductor layer 43 with a thickness of 1 μm to 5 μm is formed, a flow rate of supply gases, such as nitrogen, ammonia, hydrogen, trimethylgallium (TMGa), triethylgallium (TEGa), trimethylindium (TMIn), triethylindium (TEIn) or organometallic compound, is stopped or reduced. Thus the top surface of the n-type semiconductor layer 43 is grown unevenly and the plurality of recesses 431 are formed. In addition, recesses 431 can be formed by etching the top surface of the n-type semiconductor layer 43.

Subsequently, the conformational active layer 44, in which holes and electrons are recombined to emit light, is formed on the n-type semiconductor layer 43. The conformational active layer 44 is a single quantum well (SQW) structure or a multiple quantum well (MQW) structure. The MQW structure is comprised of two to thirty light-emitting layers/barrier layers. In a preferred embodiment, the conformational active layer 44 is composed of six to eighteen layers. The light-emitting layers can be made of Al_{X}In_{Y}Ga_{1-X-Y}N and the barrier layers can be made of Al_{I}In_{J}Ga_{1-I-J}N, wherein 0≦X<1, 0≦Y<1, X+Y<1, 0≦I<1, 0≦J<1, I+J<1, and when X, Y, I, J>0, X≠I and Y≠J. Also, the light-emitting layers/barrier layers can be made of InGaN/GaN. In this structure, the stress between the n-type semiconductor layer 43 and the conformational active layer 44 can be released with recesses 431, and thus the emission efficiency can be increased. In addition, recesses 431 are formed without the deposition process on the epitaxial layer with different materials, or without the deposition of droplets. As a result, such method does not sacrifice the quality of the epitaxial layer and does not need an epitaxial layer as the n-type semiconductor layer 43, which sacrifices the epitaxial quality in order to match the lattice constant.

At least one p-type semiconductor layer 45 is then formed on the conformational active layer 44. The p-type semiconductor layers 45 may be formed as Mg-doped GaN and InGaN multi-layers, a superlattice structure of Mg-doped AlGaN/GaN and an Mg-doped GaN layer, or other forms. The p-side electrode 46 and the n-side electrode 47 then serve to allow the current to be applied to the p-type semiconductor layers 45 and the n-type semiconductor layer 43, respectively.

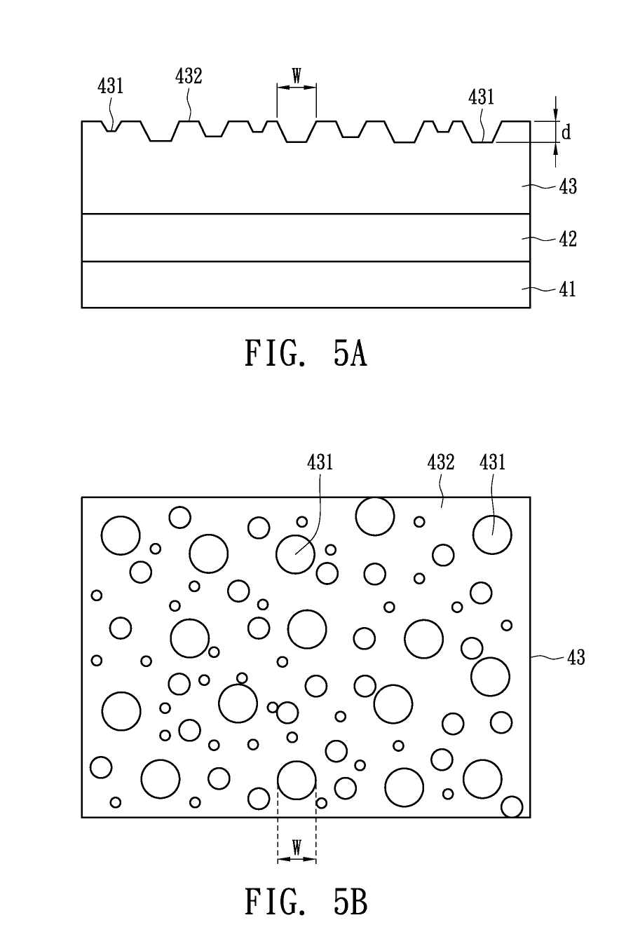

FIG. 5A is a partial cross section diagram showing a light-emitting diode of the present invention. The buffer layer 42 and the n-type semiconductor layer 43 are grown in sequence on the substrate 41. Referring to FIG. 5A, the top surface of the n-type semiconductor layer 43 is uneven and comprises the plurality of recesses 431 and the flat area 432. The depths of the accesses 431 may be larger than the depths of a single quantum well and smaller than the depth of the n-type semiconductor layer 43. In addition, a cross section of the recesses 431 is substantially of an inverted trapezoid shape, and the widths W of the upper portions of the recesses range from 0.1 um to 10 um.

FIG. 5B is a top view of a partial cross section diagram of FIG. 5A. Referring to FIG. 5B, the widths W or the diameters of the recesses 431 are not of uniform size and the distribution of recesses 431 is substantially uniform or non-uniform on the n-type semiconductor layer 43.

The above-described embodiments of the present invention are intended to be illustrative only. Those skilled in the art may devise numerous alternative embodiments without departing from the scope of the following claims.

What is claimed is:

1. A III-nitride semiconductor light-emitting device, comprising:
a substrate;
a first type semiconductor layer including a first surface and a second surface, wherein the first surface is disposed adjacent to the substrate, and the second surface has a plurality of recesses and is opposite to the first surface;
a conformational active layer formed on the second surface and within the plurality of recesses; and
a second type semiconductor layer formed on the conformational active layer.

2. The III-nitride semiconductor light-emitting device as claimed in claim 1, further comprising a buffer layer disposed between the substrate and the first type semiconductor layer.

3. The III-nitride semiconductor light-emitting device as claimed in claim 1, wherein the material of the substrate is sapphire, SiC, Si, ZnO, MgO or GaAs.

4. The III-nitride semiconductor light-emitting device as claimed in claim 1, wherein depths of the accesses are larger than a depth of a single quantum well in the active layer, and smaller than the depth of the first type semiconductor layer.

5. The III-nitride semiconductor light-emitting device as claimed in claim 1, wherein widths of upper portions of the recesses range from 0.1 um to 10 um, and widths of upper portions of the recesses are larger than widths of lower portions of the recesses.

6. The III-nitride semiconductor light-emitting device as claimed in claim 1, wherein the plurality of recesses have different sizes, and the distribution of the plurality of recesses is substantially uniform or non-uniform.

7. The III-nitride semiconductor light-emitting device as claimed in claim 1, wherein the conformational active layer is a single quantum well structure or a multiple quantum well structure.

8. The III-nitride semiconductor light-emitting device as claimed in claim 7, wherein the multiple quantum well structure comprises two to thirty light-emitting layers and barrier layers, wherein the materials of the light-emitting layers and the barrier layers are InGaN and GaN.

9. The III-nitride semiconductor light-emitting device as claimed in claim 7, wherein the multiple quantum well structure comprises two to thirty light-emitting layers and barrier layers, wherein the light-emitting layers are made of Al_{X}In_{Y}Ga_{1-X-Y}N, and the barrier layers are made of Al_{I}In_{J}Ga_{1-I-J}N, wherein 0≦X<1, 0≦Y<1, X+Y<1, 0≦I<1, 0≦J<1, I+J<1, and when X, Y, I, J>0, X≠I and Y≠J.

10. The III-nitride semiconductor light-emitting device as claimed in claim 1, wherein the first type semiconductor layer is an n-type III-nitride semiconductor layer, and the second type semiconductor layer is a p-type semiconductor layer.

11. The III-nitride semiconductor light-emitting device as claimed in claim 1, wherein the first type semiconductor layer is an n-type Si-doped GaN layer, and the second type semiconductor layer is formed as Mg-doped GaN and InGaN multi-layers, or a superlattice structure of Mg-doped AlGaN/GaN and a Mg-doped GaN layer.

12. The III-nitride semiconductor light-emitting device as claimed in claim 1, further comprising a first type electrode and a second type electrode, wherein the first type electrode is disposed on the first type semiconductor layer, and the second type electrode is disposed on the second type semiconductor layer.

13. A method for manufacturing a III-nitride semiconductor light-emitting device, comprising the steps of:
providing a substrate;
forming a first type semiconductor layer on the substrate, wherein the first type semiconductor layer includes a first surface and a second surface, the first surface is disposed adjacent to the substrate, and the second surface opposite to the first surface has a plurality of recesses;
forming a conformational active layer on the first type semiconductor layer; and
forming a second type semiconductor layer on the conformational active layer.

14. The method as claimed in claim 13, wherein the plurality of recesses are formed by etching the second surface of the first type semiconductor layer.

15. The method as claimed in claim 13, wherein the plurality of recesses are cavities formed on the second surface by controlling a flow rate of supply gas or organometallic compound applied to the formation of the first type semiconductor layer, wherein the supply gas is nitrogen, ammonia, hydrogen, TMGa, TEGa, TMIn or TEIn.

16. The method as claimed in claim 13, further comprising at least one buffer layer directly formed on the substrate.

17. The method as claimed in claim 13, wherein widths of upper portions of the recesses ranges from 0.1 um to 10 um, and depths of accesses are larger than a depth of a single quantum well in the conformational active layer, and are smaller than a depth of the first group semiconductor layer.

18. The method as claimed in claim 13, wherein the conformational active layer is formed to have a single quantum well structure or a multiple quantum well structure.

19. The method as claimed in claim 13, wherein the first type semiconductor layer is an n-type semiconductor layer, and the second type semiconductor layer is a p-type semiconductor layer.

20. The method as claimed in claim 13, wherein the first type semiconductor layer is an n-type Si-doped GaN layer, and the second type semiconductor layers are formed as Mg-doped GaN and InGaN multi-layers, or a superlattice structure of Mg-doped AlGaN/GaN and a Mg-doped GaN layer.
